(19) United States
(12) Patent Application Publication
(10) Pub. No.: US 2026/0129746 A1
(43) Pub. Date: May 7, 2026

(54) ENHANCE ISOLATION PACKAGE

(71) Applicant: Analog Devices, Inc., Wilmington, MA (US)

(72) Inventor: David Frank Bolognia, Charlestown, MA (US)

(21) Appl. No.: 18/938,154

(22) Filed: Nov. 5, 2024

(51) Int. Cl. H05K 1/02; H05K 1/03; H05K 1/11; H05K 1/18; H05K 3/12

(52) U.S. Cl. CPC H05K 1/0256; H05K 1/0393; H05K 1/111; H05K 1/181; H05K 1/189; H05K 3/1283; H05K 2201/09163; H05K 2203/0143; H05K 2203/1327

(57) ABSTRACT

An electronic device is disclosed. The electronic device can include a substrate having metal traces. The substrate can have a length and a width, such that the length is longer than the width. The electronic device can further include one or more dies disposed on a first surface of the substrate and connected to the metal traces. An encapsulant can at least partially surround the first surface and a second surface of the substrate, the second surface opposite the first surface. The electronic device can also include a first slotted aperture disposed in proximity to a first end of the substrate and a second slotted aperture disposed in proximity to a second end of the substrate opposite the first end. The encapsulant can extend through the first slotted aperture and the second slotted aperture. The substrate can be a flexible substrate.

### BACKGROUND

### Field

This disclosure relates to electric device structures and methods. In particular, some implementations are directed to methods and structures for assembling a high creepage electronic device for high voltage isolation.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Advancements have been made to improve the integration and performance of microelectronic devices. As microelectronic devices become more complex, the importance of packaging solutions and processes has been developed to address the challenges posed by demands for compact and efficient designs.

### SUMMARY

For purposes of summarizing the disclosure and the advantages achieved over the prior art, certain objects and advantages of the disclosure are described herein. Not all such objects or advantages may be achieved in any particular implementation. Thus, for example, those skilled in the art will recognize that the devices, systems, and methods may be embodied or carried out in a manner that achieves or optimizes one advantage or group of advantages as taught herein without necessarily achieving other objects or advantages as may be taught or suggested herein.

All of these implementations are intended to be within the scope of the devices, systems, and methods herein disclosed. These and other implementations will become readily apparent to those skilled in the art from the following detailed description of the implementations having reference to the attached figures, the devices, systems, and methods not being limited to any particular implementations disclosed.

In some implementations, an electronic device can include: a substrate having metal traces, the substrate having a length and a width, wherein the length is longer than the width; one or more dies disposed on a first surface of the substrate and connected to the metal traces; an encapsulant at least partially surrounding the first surface and a second surface of the substrate, the second surface opposite the first surface; and a first slotted aperture disposed in proximity to a first end of the substrate and a second slotted aperture disposed in proximity to a second end of the substrate opposite the first end, the encapsulant extending through the first slotted aperture and the second slotted aperture.

In some implementations, the substrate includes a flexible substrate. In some implementations, the electronic device includes a plurality of bond pads disposed on the second surface of the substrate, and a plurality of conductive connectors connected to the bond pads. In some implementations, the plurality of conductive connectors include a first plurality and a second plurality of conductive connectors. In some implementations, the first plurality and the second plurality of conductive connectors are spaced apart greater than the width of the substrate. In some implementations, electronic device can include a creepage distance measured between the first plurality and the second plurality of conductive connectors. In some implementations, the measured creepage distance is 15 mm.

In some implementations, the electronic device, further including at least one side of the substrate protruding from the encapsulant. In some implementations, the electronic device includes a first end side of the substrate protruding from the encapsulant. In some implementations, the electronic device includes a second end side of the substrate protruding from the encapsulant, wherein the second end is opposite the first end side. In some implementations, the substrate includes a first aperture through the first end side and a second aperture through a second end side exposed through the encapsulant. In some implementations, the electronic device includes lateral sides of the substrate extending along a portion of the length, wherein a first lateral side protrudes from the encapsulant. In some implementations, the electronic device includes a second lateral side protruding from the encapsulant, wherein the second lateral side is opposite the first lateral side.

In some implementations, the electronic device includes a perimeter patterned trace on the first surface of the substrate. In some implementations, the metal traces include copper. In some implementations, the length and the width of the substrate include an aspect ratio of 2:1. In some implementations, the length and the width of the substrate include an aspect ratio of 3:1. In some implementations, the substrate includes at least one of paper, polyethylene terephthalate (PET), and polyimide.

In some implementations, the electronic device includes a plurality of wells formed in the encapsulant on the second surface of the substrate and conductive connectors positioned within the plurality of wells, wherein a first profile of the plurality of wells in relation to a second profile of the conductive connectors provide a standoff height between the substrate and another surface. In some implementations, the electronic device includes a first gate and a second gate for injecting the encapsulant surrounding the first and second surfaces of the substrate. In some implementations, the one or more dies regulate an incoming or outgoing voltage through the electronic device.

In some implementations, an electronic device can include: a substrate having metal traces, the substrate having a length and a width, wherein the length is longer than the width; one or more dies disposed on a first surface of the substrate and connected to the metal traces, and; an encapsulant at least partially surrounding the first surface and a second surface of the substrate, the second surface opposite the first surface; and at least one side of the substrate protruding from the encapsulant.

In some implementations, the substrate includes a flexible substrate. In some implementations, the electronic device includes a plurality of bond pads disposed on the second surface of the substrate, and a plurality of conductive connectors connected to the bond pads. In some implementations, the plurality of conductive connectors include a first plurality and a second plurality of conductive connectors. In some implementations, the first plurality and the second plurality of conductive connectors are spaced apart greater than the width of the substrate. In some implementations, the electronic device includes a creepage distance measured between the first plurality and the second plurality of conductive connectors. In some implementations, the measured creepage distance is 15 mm.

In some implementations, the electronic device includes a first end side of the substrate protruding from the encapsulant. In some implementations, the electronic device includes a second end side of the substrate protruding from the encapsulant, wherein the second end side is opposite the first end side. In some implementations, the substrate includes a first aperture through the first end side and a second aperture through a second end side exposed through the encapsulant. In some implementations, the electronic device includes lateral sides of the substrate extending along a portion of the length, wherein a first lateral side protrudes from the encapsulant. In some implementations, the electronic device includes a second lateral side protruding from the encapsulant, wherein the second lateral side is opposite the first lateral side.

In some implementations, the electronic device includes a perimeter patterned trace on the first surface of the substrate. In some implementations, the metal traces include copper. In some implementations, the length and the width of the substrate include an aspect ratio of 2:1. In some implementations, the length and the width of the substrate include an aspect ratio of 3:1. In some implementations, the substrate includes at least one of paper, polyethylene terephthalate (PET), and polyimide.

In some implementations, the electronic device includes a plurality of wells formed in the encapsulant on the second surface of the substrate and conductive connectors positioned within the plurality of wells, wherein a first profile of the plurality of wells in relation to a second profile of the conductive connectors provide a standoff height between the substrate and another surface. In some implementations, the electronic device includes a first gate and a second gate for injecting the encapsulant surrounding the first and second surfaces of the substrate. In some implementations, the one or more dies regulate an incoming or outgoing voltage through the electronic device.

In some implementations, the electronic device includes a second end of the substrate protruding from the encapsulant. In some implementations, the electronic device includes a first slotted aperture disposed in proximity to a first end of the substrate and a second slotted aperture disposed in proximity to a second end of the substrate opposite the first end, the encapsulant extending through the first slotted aperture and the second slotted aperture.

In some implementations, a method for forming an electronic device can include: providing a substrate having a first surface and a second surface, the second surface opposite the first surface, and a length and a width, the length longer than the width; forming metal traces on the first surface of the substrate and mounting one or more dies on the first surface of the substrate and electrically connecting the one more dies to the metal traces; injecting an encapsulant to surround the first and second surfaces of the substrate; and forming a first slotted aperture disposed in proximity to a first end and a second slotted aperture disposed in proximity a second end of the substrate, the second end opposite the first end, the encapsulant extending through the first slotted aperture and the second slotted aperture.

In some implementations, the substrate includes a flexible substrate. In some implementations, the method includes patterning a perimeter trace on the first surface of the substrate which increases tension and reduces deformation of the substrate. In some implementations, the method includes protruding at least one side of the substrate from the encapsulant. In some implementations, the method includes protruding a first end side of the substrate from the encapsulant. In some implementations, the method includes protruding a second end side of the substrate protruding from the encapsulant, wherein the second end is opposite the first end side. In some implementations, the method includes forming a first aperture through the first end side and a second aperture through the second end side exposed through the encapsulant. In some implementations, the method includes protruding a first lateral side of lateral sides extending along the length of the substrate from the encapsulant. In some implementations, the method includes protruding a second lateral side from the encapsulant, wherein the second lateral side is opposite the first lateral side. In some implementations, the method includes forming a first gate and a second gate for injecting the encapsulant surrounding the first and second surfaces of the substrate.

In some implementations, the method includes forming a plurality of wells in the encapsulant on the second surface of the substrate by applying a force on the substrate to form depressions for fitting conductive connectors in the plurality of wells. In some implementations, forming the wells further includes forming a first plurality of wells on the first end and forming a second plurality of wells on a second end of the substrate. In some implementations, the method includes mounting a first plurality of conductive connectors in the first plurality of wells and a second plurality of conductive connectors in the second plurality of wells, wherein a first profile of the plurality of wells in relation to a second profile of the conductive connectors provide a standoff height between the substrate and another surface. In some implementations, the method includes mounting bond pads on the second surface of the substrate and forming wells in the encapsulant on the second surface of the surface, mounting and connecting conductive connectors to the bond pads, and reflowing the electronic device to electrically connect the bond pads and conductive connectors.

In some implementations, the method includes forming a plurality of electronic devices, wherein the electronic devices are attached to one another via at least one of lateral side of the substrate protruding from the encapsulant. In some implementations, forming the electronic device includes roll-to-roll processing. In some implementations, forming metal traces includes sintering the metal traces on the first surface of the substrate. In some implementations, injecting the encapsulant further includes a second end of the substrate and a second lateral side of the lateral sides protruding from the encapsulant.

### BRIEF DESCRIPTION OF THE DRAWINGS

These and other features, aspects, and advantages of the disclosure are described with reference to drawings of certain implementations, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1A illustrates a top perspective view of an exemplary electronic device.

FIG. 1B illustrates a bottom perspective view of the exemplary electronic device of FIG. 1A.

FIG. 2A illustrates a side perspective view of the exemplary electronic device of FIGS. 1A and 1B.

FIG. 2B illustrates a top perspective view of the exemplary electronic device of FIGS. 1A-2A.

FIG. 2C illustrates a bottom perspective view of the exemplary electronic device of FIGS. 1A-2B.

FIG. 2D illustrates a front and/or back perspective view of the exemplary electronic device of FIGS. 1A-2C.

FIG. 3 is a graphical flow diagram illustrating an example process for fabricating the exemplary electronic device of FIGS. 1A-2D.

### DETAILED DESCRIPTION

Although several implementations, examples, and illustrations are disclosed below, it will be understood by those of ordinary skill in the art that the devices, systems, and methods described herein extend beyond the specifically disclosed implementations, examples, and illustrations and includes other uses of the devices, systems, and methods and obvious modifications and equivalents thereof. Implementations are described with reference to the accompanying figures, wherein like numerals refer to like elements throughout. The terminology used in the description presented herein is not intended to be interpreted in any limited or restrictive manner simply because it is being used in conjunction with a detailed description of some specific implementations of the devices, systems, and methods. In addition, implementations can comprise several novel features. No single feature is solely responsible for its desirable attributes or is essential to practicing the devices, systems, and methods herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

An isolation package is an electrical component designed to ensure electrical safety and reliability in circuits, particularly when high voltages are involved. The term “isolation package” refers to the arrangement of the electronic component packaging that prevents electrical currents from unintentionally flowing between different parts of the circuit, particularly between high-voltage and low-voltage sections. Isolation packages can also ensure electrical separation between different circuit components in high-voltage applications. The design of the isolation package can provide insulation between conductive parts, which can prevent electrical current from unintentionally bridging between different voltage levels. In these high voltage environments, the risk of electrical arcing and/or breakdown is significant, so the isolation package can include features that extend the creepage distance—the shortest path along the surface of the insulating material between two conductive parts.

Creepage distance, which is the shortest path along the surface of an insulating material between conductive parts, plays a vital role in these designs. In high-voltage applications, a longer creepage distance can prevent electrical arcing and ensure that the insulating material can withstand the applied voltages without breaking down and/or allowing leakage currents. This is important in power electronics, where components like transformers, converters, and/or inverters operate at different voltage levels and require effective isolation between high and low voltage sides. By increasing the creepage distance, the package can withstand higher voltages without allowing leakage current and/or breakdown of the insulation, thereby protecting both the equipment and the users.

A proper and sufficient minimum creepage distance should protect against tracking, which is a failure mode in which an insulation surface is degraded and made at least partially conducting. Damage to insulators from tracking generally develops over time and is accelerated by various factors including excessive working voltages, humidity in the environment, contaminants in or on the insulators, corrosive materials or other pollutants including dust in the environment, humidity, and moisture levels, and even the altitude at which the electronic component is operated. Thus, the minimum creepage distance specified by regulators is a function of multiple factors including, but not necessarily limited to, the expected working voltage, the insulator material properties, and the expected working environment (e.g., dry, wet, clean, dusty, salinity, corrosive, high or low altitude, etc.).

The resistance of an insulating material to tracking may be described by a comparative tracking index (CTI), determined by placing a test voltage across the insulator until a certain amount of current flows across the insulator. Materials having a higher CTI-value are more resistant to tracking and thus require shorter minimum creepage distances to satisfy regulations. Some materials, including inorganics like glass and ceramic, are not susceptible to tracking. In generally, plastics like polyethylene are more resistant to tracking than printed circuit board material (e.g., FR4 glass-reinforced epoxy laminate material), which is turn is more resistant to tracking than glass-filled PCB FR4, which is turn is more resistant to tracking than phenolic resins.

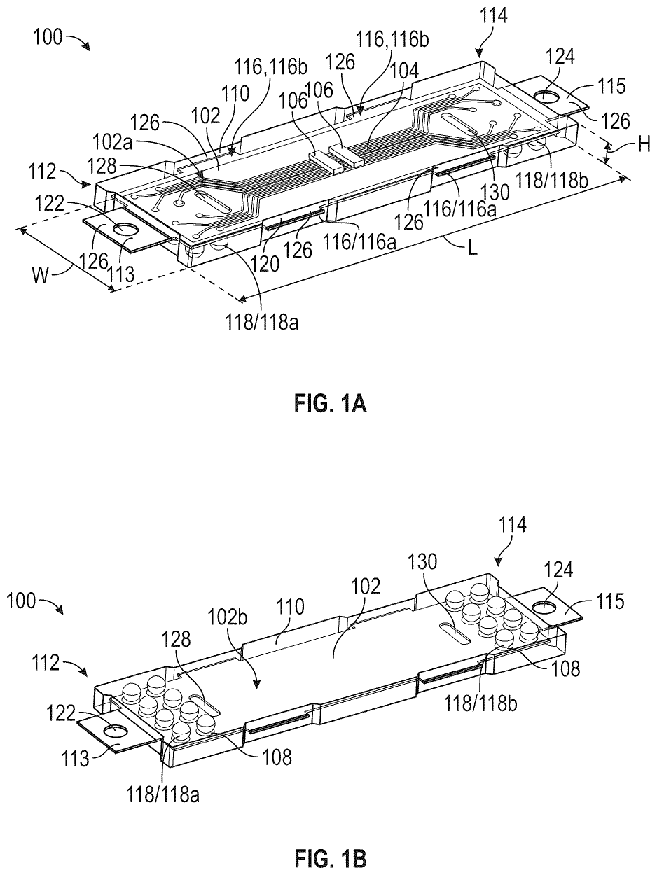

FIGS. 1A and 1B illustrates a top perspective view and a bottom perspective view, respectively, of an example electronic device 100. In some implementations, the electronic device 100 can be an isolation package. The electronic device 100 can include a substrate 102 having metal traces 104. In some implementation, the substrate 102 can be a flexible substrate composed of at least one of paper, polyethylene terephthalate (PET), and/or polyimide (PI). The substrate 102 can be composed of one or more layers with the option to add additional layers. The metal traces 104 can be composed of gold, silver, copper, aluminum, nickel, and/or any suitable metal. The substrate 102 can have a length L and a width W, where the length L is longer than the W. Additionally, the electronic device 100 can include a height that extends perpendicular to the length L and the width W. In some implementations, the length L and the width W of the substrate 102 have an aspect ratio of 2:1. In other implementations, the length L and the width W of the substrate 102 have an aspect ratio of 3:1. Flexible substrates can be useful in arrangements where it is desirable for the substrate to conform to a particular geometry employed within a system. In some implementations, flexible substrates (e.g., substrate 102) can be made of a flexible plastic material, such as polyimide or PEEK, and can include integrated bond pads, traces and leads similar to those used in conventional PCB substrates. The flexible substrate can refer to a material and/or base layer that can bend, fold, and/or conform to various shapes without losing its structural integrity. A flexible substrate can be used as the foundation for flexible PCBs in an electronic component. The flexibility of the substrate can allow the electronic components to be mounted on a surface that can bend and/or flex, enabling the creation of devices that can conform to non-planar surfaces or undergo deformation. The flexible substrate can have a Young's modulus (i.e., clastic modulus) that is less than other PCB materials such as FR-4 (i.e., more flexible). The Young's modulus is a material property that describes stiffness and is defined as the ratio of stress to strain within the elastic limit. The Young's modulus of a flexible substrate (e.g., printed circuit board (PCB)) can depend on the materials used in its construction. Flexible PCBs can be made with materials such as polyimide, which is known for its flexibility. The Young's Modulus of polyimide can be in the range of 2 to 4 GPa as compared to 35 to 40 GPa for FR-4 used in rigid PCBs. The substrate 102 can further have a flexural modulus (i.e., a measure of a material's resistance to deformation under applied bending stress that characterizes a material's stiffness in flexural or bending loading conditions) that is less when compared to other PCB materials such as FR-4. When a material is subjected to a bending force, it undergoes deformation, and the flexural modulus quantifies how much the material will deform under this stress. For example, the flexural modulus of polyimide can be 2 to 4 GPa which is less than 14 to 20 GPa of FR-4. The substrate 102 can be easily bent or folded to conform to a particular geometry, which permits contacting downstream components in a variety of configurations. Furthermore, traces (e.g., metal traces 104) and leads can be patterned on the flexible substrate in very small dimensions. For example, in some implementations, the metal traces 104 can have line widths and spaces on the order of about 15 to 20 μm, and the leads or bond pads (e.g., bond pads 108) can have widths or diameters of about 200-300 μm with similar spacing, such that the pitch is on the order of 400-600 μm.

As illustrated in FIG. 1A, one or more dies 106 can be disposed on a first surface 102a of the substrate 102. In some implementations, the dies 106 regulate an incoming or outgoing voltage through the electronic device 100. The dies 106 can be electrically and/or mechanically connected to the metal traces 104. For example, in some implementations, the dies 106 can include conductive adhesives (e.g., copper bumped) which do not need a solder cap for forming the electrical connections. Additionally, in some implementations, the dies 106 are connected to the metal traces 104 via a direct copper to copper bond with an underfill and/or utilizing a local reflow and an underfill. In some implementations, the dies 106 are positioned at approximately one half of length L and the at approximately one half of the width W of the substrate 102. The dies 106 can ensure that signals and/or power are transmitted between different circuit parts while maintaining electrical isolation. In some implementations, the electronic device 100 can include additional integrated circuits (ICs), passive components, laminate transformers, etc. The electronic device 100 can further include a perimeter patterned trace 120 on the first surface 102a of the substrate 102. The perimeter patterned trace can assist with increasing tension and/or reducing deformation of the substrate 102.

A plurality of bond pads 108 can be disposed on a second surface 102b of the substrate 102. The second surface 102b is on an opposite side of the substrate 102 from the first surface 102a. The bond pads 108 can be composed of flat areas on the second surface 102b of the substrate 102. The bond pads 108 can provide for electrical connections to and/or from the electronic device 100. The bond pads 108 can serve as the points of contact for electrical terminals (e.g., conductive adhesives such as solder balls) or other interconnects that connect the substrate 102 to the external circuitry, such as within a package and/or on a circuit board.

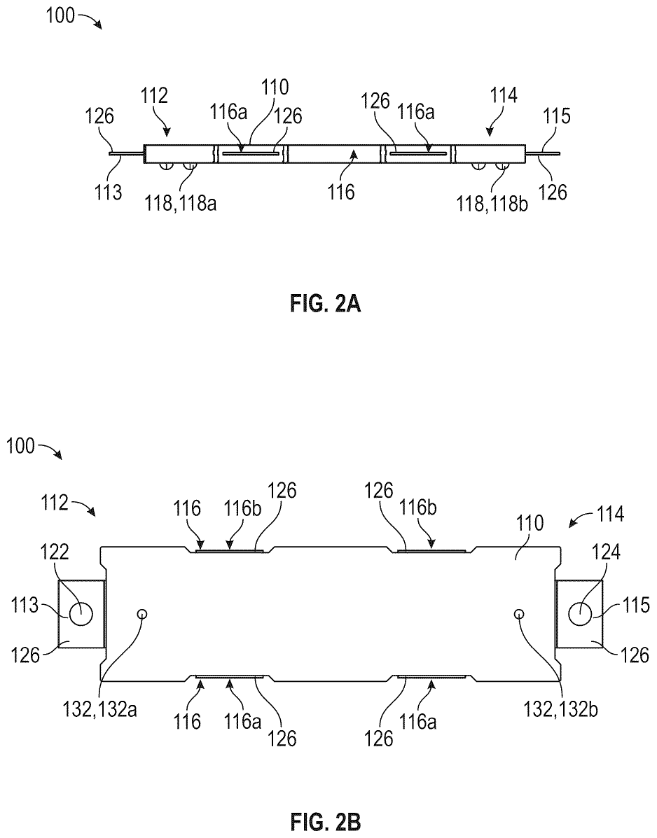

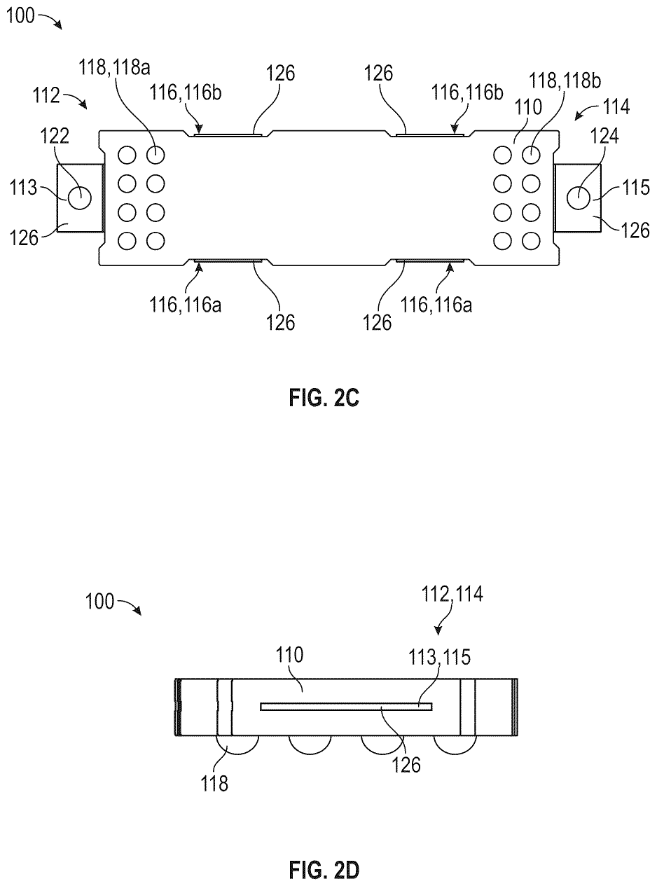

The electronic device 100 can further include an encapsulant 110 (e.g., a molding compound). The encapsulant 110 can at least be molded over and/or surround the first surface 102a and the second surface 102b of the substrate 102 to form a two-sided package. A two-sided package, or a mold with two halves that close tightly, helps prevent mold flash by ensuring a better seal during the injection molding process. This design allows for improved clamping force, which evenly distributes pressure and minimizes the chances of molten material (e.g., encapsulant 110) leaking out. Additionally, two-sided molds can be aligned to reduce gaps or mismatches at the parting line where mold flash can occur. The two-sided package molds can also feature enhanced venting that allows trapped air to escape without compromising the seal around the mold. By addressing these factors, a two-sided package maintains the integrity of the mold during the injection process, thereby reducing the likelihood of mold flash. For example, by ensuring that excess material (e.g., encapsulant 110) does not seep out of the mold cavity during the injection molding process, mold flash can be prevented on the surfaces 102a, 102b of the substrate 102. The encapsulant 110 can also protect the electrical components mounted to the substrate 102 from environmental factors such as moisture, mechanical stress, and/or contaminants. In some implementations, the encapsulant 110 comprises an organic mold compound. In some implementations, as described below, the electronic device 100 during manufacturing includes a first gate 132a and/or a second gate 132b for injecting the encapsulant 110 surrounding the first surface 102a and the second surface 102b of the substrate 102 (see FIG. 2B).

As shown in FIGS. 1A and 1B, one or more sides of the substrate 102 can protrude from the encapsulant 110. For example, a first end side 113 at the first end 112 of the substrate 102 can protrude from the encapsulant 110. In some implementations, a second end side 115 at the second end 114 of the substrate 102 also protrudes from the encapsulant 110. The second end side 115 can be on an opposite side of the substrate 102 from the first end side 113. The substrate 102 can include a first aperture 122 (e.g., tooling hole) extending through the first end side 113. In some implementations, the substrate 102 includes a second aperture 124 (e.g., tooling hole) extending through a second end side 115. The first aperture 122 and/or second aperture 124 can assist with alignment during manufacturing and with positioning of components. The first aperture 122 and/or second aperture 124 can allow for the substrate 102 to be fixed during processing, preventing movement that could cause defects. In high-volume production, the first aperture 122 and/or second aperture 124 can assist with consistency and repeatability, reducing errors and improving yield. Additionally, the first aperture 122 and/or second aperture 124 can support automated processes by providing a standardized way for machinery to handle and position the substrate 102, contributing to the overall quality and reliability. The substrate can also include lateral sides 116 that extend along at least a portion of the length L of the substrate 102. In some implementations, a first lateral side 116a of the substrate 102 can protrude from the encapsulant 110. In some implementations, a second lateral side 116b of the substrate 102 also protrudes from the encapsulant 110. The second lateral side 116b can be on an opposite side of the substrate 102 from the first lateral side 116a.

The exposed portions (e.g., sides) of the substrate 102 extending from the encapsulant 110 at the first end 112 and/or second end 114 as well as the lateral sides 116 can compose tie bars 126. For example, the tie bars 126 can be positioned at the first end side 113, the second end side 115, the first lateral side 116a and/or the second lateral side 116b. The tie bars 126 can provide mechanical stability and alignment during a manufacturing process. The tic bars 126 can also ensure that the substrate 102 remains in place, preventing movement or shifting during processes like molding, wire bonding, and/or encapsulation. This stability helps with maintaining proper alignment of the different layers and/or components, which also helps to ensure electrical connectivity and the overall functionality. Additionally, tie bars 126 can facilitate handling and transportation during manufacturing by providing a rigid structure that reduces the risk of damage. The tie bars 126 can help distribute mechanical stresses evenly across the substrate 102, minimizing the chances of warping and/or cracking.

In some implementations, the substrate 102 of the electronic device 100 can further include a first slotted aperture 128 disposed in proximity to the first end 112 and/or a second slotted aperture 130 disposed in proximity to a second end 114 of the substrate 102. During encapsulation, the first slotted aperture 128 and/or second slotted aperture 130 can allow the encapsulant 110 to flow from the first surface 102a to the second surface 102b of the substrate 102 and vice versa. Additionally, the first slotted aperture 128 and/or second slotted aperture 130 can possess any shape and/or configuration for allowing the encapsulant 110 to pass through.

As shown in FIG. 1B, a plurality of conductive connectors 118, such as a conductive adhesive (e.g., solder balls), can be disposed on the second surface 102b of the substrate 102 for mounting the electronic device 100 to another package and/or to external circuitry. The conductive connectors 118 can be made of a solder alloy, which can be composed of tin, lead, and/or tin-silver-copper combinations. The conductive connectors 118 can be aligned and electrically and/or mechanically connected to the bond pads 108. The conductive connectors 118 can be arranged to further form a ball grid array (BGA) along the second surface 102b. In some implementations, the conductive connectors 118 can form a plurality of BGA's along the second surface 102b of the substrate 102. The conductive connectors 118 can be reflowed causing the conductive connectors 118 to form strong, conductive bonds with the bond pads 108 and/or pads of an external package. In some implementations, the conductive connectors 118 include a first plurality of conductive connectors 118a and a second plurality of conductive connectors 118b. The first plurality of conductive connectors 118a and the second plurality of conductive connectors 118b can be spaced apart greater than the width W of the substrate 102. Additionally, a creepage distance can measured between the first plurality of conductive connectors 118a and the second plurality of conductive connectors 118b. In some implementations, the measured creepage distance can be between approximately 1 mm to 30 mm, between approximately 2.5 mm to 27.5 mm, between approximately 5 mm to 25 mm, between approximately 7.5 mm to 22.5 mm, between approximately 10 mm to 20 mm, between approximately 12 mm to 18 mm, between approximately 12.5 mm to 17.5 mm, or approximately 15 mm.

The substrate 102 can also include a plurality of wells 134 formed in the encapsulant 110 on the second surface 102b of the substrate 102. For example, the wells 134 can be formed during the encapsulation of electronic device 100 (e.g., while forming the two-sided package). The wells 134 can be composed of cavities and/or recessed areas in the encapsulant 110 in which the conductive connectors 118 can be disposed in (e.g., housed). The configuration of the conductive connectors 118 and/or wells 134 can control a standoff height (e.g., the height of a solder joint after a component has been mounted) and/or ball collapse (e.g., the reduction in height of a conductive adhesive, such as solder balls, during reflow that causes the conductive adhesive to melt) of the electronic device 100 by configuring a first profile of the wells 134, the first profile comprising the dimensions and/or geometry of the wells 134, in relation to a second profile of the conductive connectors 118, the second profile comprising the dimensions and/or geometry of the conductive connectors 118. The depth, diameter, and/or contour of the wells 134, along with the size and/or shape of the conductive connectors 118, can influence the ball collapse during reflow, thus ensuring consistent electrical connections and mechanical integrity within the package. The shape and size of the wells 134 and the size of the conductive connectors 118 can provide a defined standoff height between the substrate 102 and another surface (e.g., a surface the electronic device 100 is mounted to). The wells 134 can expose bond pads 108 and/or other connectors, as well as electrodes, and provide accessibility for external connections, testing, and/or further processing.

FIGS. 2A-2D illustrate various perspective views of the electronic device 100 with the encapsulant 110. FIG. 2A illustrates a side perspective view of the electronic device 100. FIG. 2B illustrates a top perspective view of the electronic device 100. FIG. 2C illustrates a bottom perspective view of the electronic device 100. FIG. 2D illustrates a front and/or back perspective view of the electronic device 100. As shown in FIGS. 2A-2D, the electronic device 100 can include one or more sides of the substrate 102 extending through the encapsulant 110 to form tie bars 126. For example, the electronic device 100 can include first end side 113 at the first end 112, second end side 115 at the second end 114, and one or more first lateral sides 116a and second lateral side 116b of the lateral sides 116 protruding from the encapsulant 110.

As shown in FIG. 2B, the encapsulant can include one or more gates 132 (e.g., first gate 132a and/or a second gate 132b) for injecting the encapsulant 110 surrounding the first surface 102a and the second surface 102b of the substrate 102. The gates 132 can compose an opening and/or hole through which the encapsulant 110 (e.g., epoxy, polymer, resin, etc.) flows to fill a mold and encapsulate the substrate 102 to at least partially cover and protect the substrate 102 from environmental damage, mechanical stress, and/or contaminants. The gates 132 can control the flow of the encapsulant 110 and ensure that the encapsulant 110 spreads evenly over the substrate 102, providing a uniform encapsulation layer. After the encapsulant 110 sets, the gates 132 may be trimmed and/or cleaned.

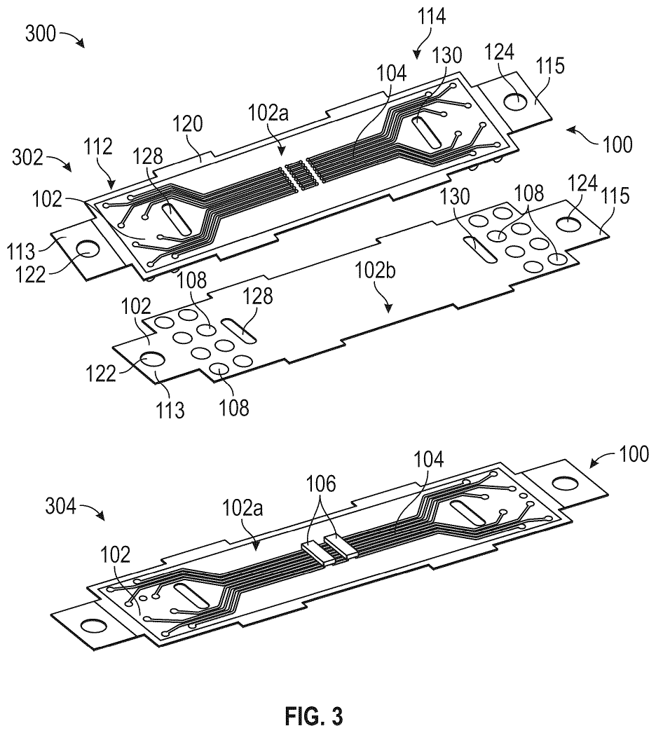

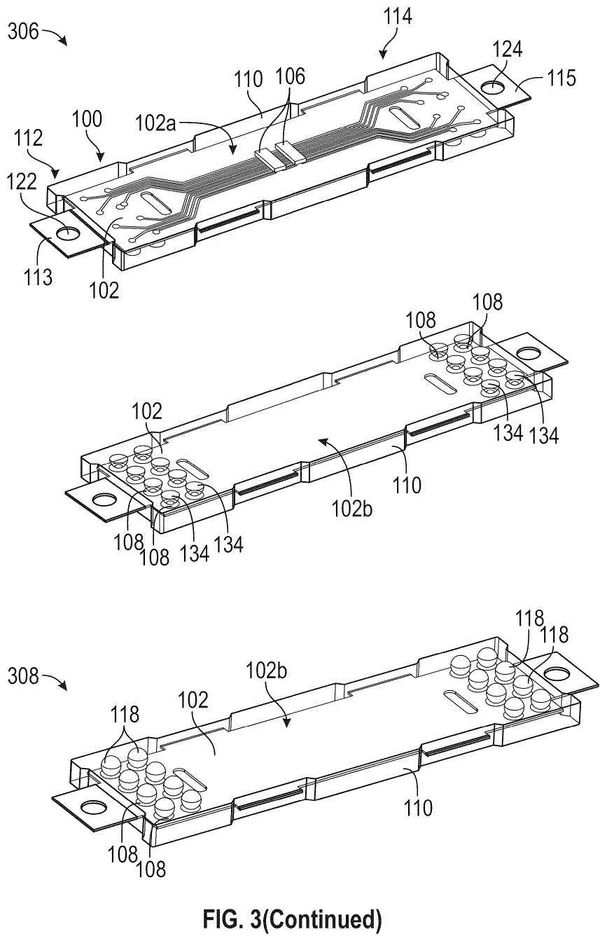

FIG. 3 is a graphical flow diagram illustrating an example process 300 for fabricating the electronic device 100. In some implementations, the process 300 can compose roll-to-roll processing. Roll-to-roll (R2R) processing for is a high-throughput manufacturing technique where substrates (e.g., flexible substrates) are continuously fed from a roll, processed (e.g., patterning, etching, or deposition), and then rewound onto another roll. This method allows for the large-scale, cost-effective production of electronics, sensors, and/or integrated circuits on substrates. At step 302, the substrate 102 having first surface 102a and second surface 102b can be provided. The step 302 can be composed of any suitable material such as PET, paper, PI, etc. as mentioned above. The substrate 102 can also include one or more layers with the option to add additional layers. The substrate 102 can be cut and/or diced to form any desired dimensions and/or shape. For example, the substrate 102 can include a first end 112 in which a first end side 113 includes a first aperture 122 through the substrate 102. The substrate 102 can further include a second end 114 in which a second end side 115 includes a second aperture 124 through the substrate 102. Additionally, a first slotted aperture 128 in proximity to the first end 112 and/or a second slotted aperture 130 in proximity to the second end 114 can also be formed through the substrate 102. The metal traces 104 can be disposed (e.g., sintered, patterned, printed, etc.) onto the first surface 102a. As mentioned above, the metal traces 104 can be composed of gold, silver, copper, aluminum, nickel, and/or any suitable metal. The perimeter patterned trace 120 can also be disposed (e.g., patterned, printed, etc.) around the perimeter of the first surface 102a. The trace 120 can increase tension and reduce deformation of the substrate 102. The plurality of bond pads 108 can be disposed on the second surface 102b to form flat areas on the second surface 102b of the substrate 102.

At step 304, the one or more dies 106 can be disposed on a first surface 102a of the substrate 102. The dies 106 can be electrically and/or mechanically connected to the metal traces 104. In some implementations, the dies 106 can be positioned at approximately one half of length L and the at approximately one half of the width W of the substrate 102.

At step 306, the encapsulant 110 (e.g., a molding compound) can encapsulate the first surface 102a and the second surface 102b of the substrate 102 to protect the electronic device 100 from environmental factors such as moisture, mechanical stress, and/or contaminants. The encapsulant 110 can extend through the first slotted aperture 128 and/or second slotted aperture 130 to allow the encapsulant 110 to flow from the first surface 102a to the second surface 102b and vice versa. Additionally, the first slotted aperture 128 and/or second slotted aperture 130 can prevent the buildup of pressure on the first surface 102a and/or second surface 102b during encapsulation, as well as improve adhesion of the encapsulant 110, by allowing the encapsulant 110 to flow evenly through the first slotted aperture 128 and/or second slotted aperture 130. As shown at step 306, the first end side 113 at the first end 112 and/or the second end side 115 at the second end 114 can protrude from the encapsulant 110. Additionally, one or more lateral sides 116 of the substrate 102 can also protrude from the encapsulant 110. For example, the first lateral side 116a and/or the second lateral side 116b of the substrate 102 can protrude from the encapsulant 110. Furthermore, a plurality of wells 134 can be formed in the encapsulant 110 on the second surface 102b of the substrate 102.

At step 308, the plurality of conductive connectors 118, such as a conductive adhesive (e.g., solder balls), can be disposed on the second surface 102b of the substrate 102 for mounting the electronic device 100 to another package and/or to external circuitry. The conductive connectors 118 can be made of a solder alloy, which can be composed of tin, lead, and/or tin-silver-copper combinations. The conductive connectors 118 can be aligned and electrically and/or mechanically connected to the bond pads 108. In some implementations, the conductive connectors 118 include a first plurality of conductive connectors 118a and a second plurality of conductive connectors 118b. In some implementations, the substrate 102 includes a plurality of wells 134 formed in the encapsulant 110 on the second surface 102b of the substrate 102. The plurality of wells 134 can be formed on the second surface 102b by applying a force on the substrate 102 during encapsulation to form depressions in the encapsulant 110 for fitting and/or housing the conductive connectors 118 in the wells 134. The wells 134 are composed of cavities and/or recessed area in the encapsulant 110 in which the conductive connectors 118 can be disposed in.

In the foregoing specification, the systems and processes have been described with reference to specific implementations thereof. It will, however, be evident that various modifications and changes may be made thereto without departing from the broader spirit and scope of the implementations disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the implementations of the disclosed systems and processes. Any methods disclosed herein need not be performed in the order recited. Thus, it is intended that the scope of the systems and processes herein disclosed should not be limited by the particular implementations described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementations. Conversely, various features that are described in the context of a single implementation also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every implementation.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more implementations.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various implementations described above can be combined to provide further implementations. The accompanying claims and their equivalents are intended to cover such forms or modifications as would fall within the scope and spirit of the disclosure.

Several illustrative examples of electronic devices and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed devices, systems, and methods. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of several devices, systems, and methods have been described herein. Not all, or any such advantages are necessarily achieved in accordance with any particular example of the devices, systems, and methods disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles and the novel features disclosed herein.

What is claimed is:

1. An electronic device, the electronic device comprising:
a substrate having metal traces, the substrate having a length and a width, wherein the length is longer than the width;
one or more dies disposed on a first surface of the substrate and connected to the metal traces;
an encapsulant at least partially surrounding the first surface and a second surface of the substrate, the second surface opposite the first surface; and
a first slotted aperture disposed in proximity to a first end of the substrate and a second slotted aperture disposed in proximity to a second end of the substrate opposite the first end, the encapsulant extending through the first slotted aperture and the second slotted aperture.

2. The electronic device of claim 1, wherein the substrate comprises a flexible substrate.

3. The electronic device of claim 1, further comprising a plurality of bond pads disposed on the second surface of the substrate, and a plurality of conductive connectors connected to the bond pads, wherein the plurality of conductive connectors comprise a first plurality and a second plurality of conductive connectors and a creepage distance measured between the first plurality and the second plurality of conductive connectors.

4. The electronic device of claim 1, further comprising at least one side of the substrate protruding from the encapsulant.

5. The electronic device of claim 4, further comprising a first end side of the substrate protruding from the encapsulant, a second end side of the substrate protruding from the encapsulant, wherein the second end is opposite the first end side, wherein the substrate comprises a first aperture through the first end side and a second aperture through a second end side exposed through the encapsulant.

6. The electronic device of claim 4, further comprising lateral sides of the substrate extending along a portion of the length, wherein a first lateral side protrudes from the encapsulant, and a second lateral side protruding from the encapsulant, wherein the second lateral side is opposite the first lateral side.

7. The electronic device of claim 1, further comprising a plurality of wells formed in the encapsulant on the second surface of the substrate and conductive connectors positioned within the plurality of wells, wherein a first profile of the plurality of wells in relation to a second profile of the conductive connectors provide a standoff height between the substrate and another surface.

8. An electronic device, the electronic device comprising:
a substrate having metal traces, the substrate having a length and a width, wherein the length is longer than the width;
one or more dies disposed on a first surface of the substrate and connected to the metal traces, and;
an encapsulant at least partially surrounding the first surface and a second surface of the substrate, the second surface opposite the first surface; and
at least one side of the substrate protruding from the encapsulant.

9. The electronic device of claim 8, wherein the substrate comprises a flexible substrate.

10. The electronic device of claim 8, further comprising a plurality of bond pads disposed on the second surface of the substrate, and a plurality of conductive connectors connected to the bond pads.

11. The electronic device of claim 8, further comprising a first end side of the substrate protruding from the encapsulant, and a second end side of the substrate protruding from the encapsulant, wherein the second end side is opposite the first end side, wherein the substrate comprises a first aperture through the first end side and a second aperture through a second end side exposed through the encapsulant.

12. The electronic device of claim 8, further comprising lateral sides of the substrate extending along a portion of the length, wherein a first lateral side protrudes from the encapsulant, and a second lateral side protruding from the encapsulant, wherein the second lateral side is opposite the first lateral side.

13. The electronic device of claim 8, further comprising, further comprising a plurality of wells formed in the encapsulant on the second surface of the substrate and conductive connectors positioned within the plurality of wells, wherein a first profile of the plurality of wells in relation to a second profile of the conductive connectors provide a standoff height between the substrate and another surface.

14. The electronic device of claim 8, further comprising a first slotted aperture disposed in proximity to a first end of the substrate and a second slotted aperture disposed in proximity to a second end of the substrate opposite the first end, the encapsulant extending through the first slotted aperture and the second slotted aperture.

15. A method for forming an electronic device, the method comprising:
providing a substrate having a first surface and a second surface, the second surface opposite the first surface, and a length and a width, the length longer than the width;
forming metal traces on the first surface of the substrate and mounting one or more dies on the first surface of the substrate and electrically connecting the one more dies to the metal traces;
injecting an encapsulant to surround the first and second surfaces of the substrate; and
forming a first slotted aperture disposed in proximity to a first end and a second slotted aperture disposed in proximity a second end of the substrate, the second end opposite the first end, the encapsulant extending through the first slotted aperture and the second slotted aperture.

16. The method of claim 15, further comprising patterning a perimeter trace on the first surface of the substrate which increases tension and reduces deformation of the substrate.

17. The method of claim 15, further comprising protruding at least one side of the substrate from the encapsulant.

18. The method of claim 17, further comprising protruding a first end side of the substrate from the encapsulant, protruding a second end side of the substrate protruding from the encapsulant, wherein the second end is opposite the first end side, and forming a first aperture through the first end side and a second aperture through the second end side exposed through the encapsulant.

19. The method of claim 17, further comprising protruding a first lateral side of lateral sides extending along the length of the substrate from the encapsulant, and protruding a second lateral side from the encapsulant, wherein the second lateral side is opposite the first lateral side.

20. The method of claim 15, further comprising forming a plurality of wells in the encapsulant on the second surface of the substrate by applying a force on the substrate to form depressions for fitting conductive connectors in the plurality of wells, wherein forming the wells further comprises forming a first plurality of wells on the first end and forming a second plurality of wells on a second end of the substrate, and mounting a first plurality of conductive connectors in the first plurality of wells and a second plurality of conductive connectors in the second plurality of wells, wherein a first profile of the plurality of wells in relation to a second profile of the conductive connectors provide a standoff height between the substrate and another surface.
